(19) United States
(12) Patent Application Publication
(10) Pub. No.: US 2025/0366311 A1
(43) Pub. Date: Nov. 27, 2025

(54) Composite Materials, Devices, and Methods of Encapsulating Perovskites

(71) Applicant: The Florida State University Research Foundation, Inc., Tallahassee, FL (US)

(72) Inventors: Hanwei Gao, Tallahassee, FL (US); Jue Gong, Tallahassee, FL (US); Brendon Tyler Jones, Tallahassee, FL (US); Moein Adnani, Tallahassee, FL (US)

(21) Appl. No.: 19/287,139

(22) Filed: Jul. 31, 2025

Related U.S. Application Data
(62) Division of application No. 18/160,508, filed on Jan. 27, 2023.
(60) Provisional application No. 63/304,342, filed on Jan. 28, 2022.

(51) Int. Cl. H10K 50/844; H10K 30/88; H10K 85/50

(52) U.S. Cl. CPC H10K 50/844; H10K 30/88; H10K 85/50

(57) ABSTRACT

Methods of encapsulating perovskites, such as metal halide perovskites, that may include depositing a nitride or an oxide on a film that includes a perovskite. Composite materials that include a perovskite layer and a layer of a nitride or an oxide. Devices, such as electronic devices, that include composite materials.

### CROSS-REFERENCE TO RELATED APPLICATIONS

This application is a divisional of U.S. patent application Ser. No. 18/160,508, filed Jan. 27, 2023, which claims priority to U.S. Provisional Patent Application No. 63/304,342, filed Jan. 28, 2022, which is incorporated herein by reference.

### STATEMENT REGARDING FEDERALLY SPONSORED RESEARCH OR DEVELOPMENT

This invention was made with government support under Contract No. 2131610, awarded by the National Science Foundation. The government has certain rights in this invention.

### BACKGROUND

Organic-inorganic hybrid perovskites have shown high performance in optoelectronic devices, such as solar cells (H. Min, et al. Nature 2021, 598, 444; J. Tong, et al. Matter 2021, 4, 1365), light and radiation detectors (J. Zhao, et al. Nat. Photonics 2020, 14, 612; Y. He, et al. Nat. Photonics 2021, 15, 36), light-emitting diodes, and lasers (H. Zhu, et al. Nat. Mater. 2015, 14, 636; Y. Fu, et al. Nano Lett. 2016, 16, 1000). The remarkable performance likely stems primarily from the pronounced photoresponse (both in optical absorption and emission) and efficient charge transport. While the functionalities have been demonstrated successfully in research laboratories, development of viable devices remains challenging. Most of the devices showed rapid performance losses under continuous operation.

Among the factors that are likely responsible for the observed instability is ion migration, which can be particularly difficult to suppress. It has been shown, both theoretically and experimentally, that ions in most, if not all, hybrid perovskites are relatively mobile due to the soft nature of the crystal lattices, and could be even more active under external stresses such as moisture (chemical), illumination (optical), or electrical biases (Y. Yuan, et al. Adv. Energy Mater. 2016, 6, 1501803; J. M. Howard, et al. J. Phys. Chem. Lett. 2018, 9, 3463; C. J. Tong, et al. ACS Energy Lett. 2017, 2, 1997; J. Wei, et al. Adv. Energy Mater. 2021, 11, 2002326). Therefore, the degradation can be twofold: in the bulk of the perovskites, the collective motion of ions could leave behind aggregates of vacancies, which may disrupt the integrity of crystal lattices; at hetero-interfaces, on the other hand, ions in the perovskites could migrate and react with neighboring layers, or vice versa. Many efforts have been made to address the former problem, leaving the latter largely overlooked in previous research.

A potential approach to inhibit the cross-interface ion migration and suppress the interfacial reactions is to passivate the interface with a layer of inert material. By assembling materials in a layer-by-layer fashion at the atomic scale, atomic layer deposition (ALD) is known for creating conformal, pinhole-free thin films with atomic precision in thickness (S. M. George, Chem. Rev. 2010, 110, 111).

Conducting ALD directly on the hybrid perovskites, however, is a challenge. The vulnerable surface chemistry can make perovskites highly sensitive to conditions commonly used in ALD processes, such as water exposure and elevated temperature. Although some attempts have been made to show the potentially desirable effects of ALD interlayers in perovskite-based devices (D. Koushik, Energy Environ. Sci. 2017, 10, 91; C. Das, et al. Cell Reports Phys. Sci. 2020, 1, 100112; K. O. Brinkmann, et al. Sol. RRL 2020, 4, 1900332; M. Kot, et al. ChemSusChem 2018, 11, 3640), the results are inconsistent in terms of the processing conditions, coating quality, and level of damages to the underlying perovskites (I. S. Kim, et al. J. Mater. Chem. A 2015, 3, 20092; A. Hultqvist, et al. ACS Appl. Mater. Interfaces 2017, 9,29707; A. F. Palmstrom, et al. Adv. Energy Mater. 2018, 8, 1800591; A. Hultqvist, et al. ACS Appl. Energy Mater. 2021, 4, 510).

There remains a need for methods for encapsulating perovskites, including methods that rely on ALD, despite the sensitivity of perovskites.

### BRIEF SUMMARY

Provided herein are methods of encapsulating perovskites, including methods in which a nanoscale, pinhole-free oxide or nitride layer is coated directly on a perovskite, such as CH₃NH₃PbI₃, using a deposition technique, such as ALD. A nitride or oxide film may protect underlying perovskite films for extended periods without noticeable or undesirable decays in structural and/or optical properties. The encapsulated films herein may be chemically impermeable, provide complete surface coverage, be sufficiently thin to avoid undesirable impedance of charge carrier transport for optoelectronic functionalities, or a combination thereof. In some embodiments, encapsulating hybrid perovskites by the methods provided herein suppresses undesirable interfacial reactions without inhibiting the desirable transport of charge carriers.

In one aspect, methods of encapsulating materials, such as films, are provided. In some embodiments, the methods of encapsulation include providing a film that includes a perovskite, and depositing an oxide or a nitride on a surface of the film that includes a perovskite. AFD may be used to deposit the oxide or the nitride. The film may include any perovskite, and, in some embodiments, the perovskite is a 3D perovskite or a 2D perovskite.

In another aspect, composite materials are provided. In some embodiments, the composite materials include a first film and a second film arranged on the first film. The first film may include a perovskite, and have a first side. The second film may be disposed on the first side of the first film. The second film may include an oxide or a nitride.

In yet another aspect, electronic devices are provided. The electronic devices may include any one or more of the composite materials provided herein. The electronic devices may include solar cells or light emitting diodes. In some embodiments, the composite materials provided herein are emissive layers, light-absorbing layers, or charge-transporting layers in the electronic devices.

Additional aspects will be set forth in part in the description which follows, and in part will be obvious from the description, or may be learned by practice of the aspects described herein. The advantages described herein may be realized and attained by means of the elements and combinations particularly pointed out in the appended claims. It is to be understood that both the foregoing general description and the following detailed description are exemplary and explanatory only and are not restrictive.

### BRIEF DESCRIPTION OF THE DRAWINGS

FIG. 1A depicts a cross-section of an embodiment of a composite material.

FIG. 1B depicts a cross-section of an embodiment of a composite material.

FIG. 1C depicts an energy-dispersive X-ray spectrum (EDS) of a cross-section of the embodiment of the oxide layer depicted in FIG. 1A and FIG. 1B.

FIG. 2 depicts a plane-view EDS of an embodiment of a composite material.

FIG. 3A and FIG. 3B depict steady-state photoluminescence (PL) spectra (left panel) and X-ray diffraction (XRD) patterns (right panel) of an embodiment of a surface-treated perovskite before and after (FIG. 3A) 20 cycles of plasma-assisted and (FIG. 3B) 10+90 cycles of hybrid ALD at 90° C.

FIG. 4 is a schematic of an embodiment of a functionalized perovskite film disposed on an embodiment of a substrate.

FIG. 5A is a schematic of an embodiment of a composite material.

FIG. 5B depicts PL spectra and XRD data of embodiments of composite materials.

FIG. 6 depicts PL spectra and XRD data of embodiments of composite materials.

FIG. 7 depicts XRD data collected for an embodiment of a composite material.

### DETAILED DESCRIPTION

Provided herein are methods of encapsulating perovskites, including methods in which a nanoscale, pinhole-free oxide or nitride layer is coated directly on a perovskite, such as CH₃NH₃PbI₃, using ALD. The oxide or nitride films herein can provide remarkable protection to the underlying perovskite films; for example, some embodiments of the encapsulated perovskite films can withstand hours of contact with various solvents without noticeable decays in structural and/or optical properties.

### Composite Materials

In one aspect, composite materials are provided. The composite materials may include at least two films; a first film that includes a perovskite, and a second film that includes an oxide or a nitride. In some embodiments, the first film consists of the perovskite. In some embodiments, the first film includes the perovskite, and, optionally, one or more other materials, such as a matrix material. In some embodiments, the second film consists of the oxide or the nitride.

In some embodiments, the composite materials include a first film including a perovskite, the first film having a first side; and a second film including a first oxide or a first nitride, wherein the second film is disposed on the first side of the first film.

As used herein, the phrase “disposed on” indicates that two films, such as a first film “disposed on” a second film, are in direct physical contact with each other.

In some embodiments, the film including a perovskite material is disposed on a substrate. The substrate may be disposed on a second side of the film that includes a perovskite material, thereby forming, in some embodiments, a structure in which the film that includes the perovskite material is between the substrate and the film including an oxide or a nitride.

The substrate generally may include any known material. In some embodiments, the substrate includes a p-type material, such as p-type silicon. In some embodiments, the substrate is a layer of a device, such as a device described herein. For example, if a film including a perovskite material is a charge-transporting layer of a device, then the substrate may be a charge-injection layer of the device.

The second film that includes a first oxide or a first nitride may be disposed on all or a portion of the first side of the film that includes the perovskite material. In other words, the first side of the film that includes the perovskite material may be partially or entirely coated with the second film that includes a first oxide or a first nitride.

The composite materials described herein may include a third film. In some embodiments, the composite materials include a third film disposed on the second film that includes the first oxide or the first nitride, wherein the second film is arranged between the first film that includes a perovskite and the third film. The third film may include a second oxide or a second nitride. The second oxide and/or the second nitride of the third film may be identical to or different than the first oxide and the second oxide of the second layer.

A film that includes an oxide or a nitride, such as the foregoing “second film” and/or “third film”, may have any desirable thickness, such as a thickness capable of providing effective protection of the perovskite layer. In some embodiments, a film including the oxide or the nitride, such as the second and/or third film, independently has a thickness of about 3 nm to about 12 nm, about 5 nm to about 10 nm, about 6 nm to about 8 nm, or about 7 nm.

A film that includes a perovskite, such as the “first film” described herein, generally may have any thickness. Typically, a thickness of a film that includes a perovskite may be selected based on the intended use of the film. A thickness, for example, may be selected to achieve a desirable durability, conductivity, operational voltage, etc.

In some embodiments, the first side of the film including the perovskite is functionalized. The functionalization of the first side of a film including a perovskite may ensure, or increase the likelihood, that desired coverage of the first side with the second film is achieved (see Examples). In some embodiments, the first side of the film including the perovskite is functionalized with a thiol. For example, the first side of the film that includes a perovskite may be contacted with a compound that includes a thiol moiety, such as a compound that includes a thiol moiety and an alcohol moiety, e.g., 2-mercaptoethanol. The compound that includes the thiol moiety and the alcohol moiety may be an organic compound.

### Methods

In another aspect, methods of encapsulation are provided, including methods of encapsulating a perovskite layer. A perovskite layer is “encapsulated” when at least part of the perovskite layer is contacted with a nitride layer or an oxide layer.

In some embodiments, the methods include providing a film that includes a perovskite; and depositing an oxide or a nitride on a surface of the film comprising the perovskite.

The depositing of the oxide or the nitride may be achieved by any known technique. In some embodiments, chemical vapor deposition is used to deposit the oxide or the nitride. In some embodiments, AFD is used to deposit the oxide or the nitride. When the depositing of the oxide or the nitride on the surface of the film that includes the perovskite is complete, the oxide or the nitride may be present as a film on the surface of the film that includes the perovskite.

As described herein, a layer including a perovskite may be disposed on a substrate. In some embodiments, the providing of a film that includes a perovskite may include providing a multi-layer film that includes a perovskite-containing film and a substrate, wherein the perovskite-containing film is disposed on the substrate. In some embodiments, the providing of a film that includes a perovskite includes disposing the film that includes a perovskite on a substrate.

In some embodiments, the methods include treating a surface of the film that includes the perovskite. The surface of the film that is treated may include all or a portion of the surface of the film on which an oxide or a nitride will be deposited. The treating of the surface may include contacting the surface with a fluid, such as a vapor of or including one or more compounds. The treating of the surface may functionalize the surface by bonding one or more compounds to the surface. The bonding may include the formation of a covalent bond and/or one or more attractive, non-covalent forces.

In some embodiments, the treating of a surface of the film includes contacting the surface of the film with a fluid, such as a vapor, that includes a compound that includes a thiol, an alcohol, or a combination thereof. In some embodiments, the methods include treating the surface of the film that includes the perovskite with a vapor that includes 2-mercaptoethanol prior to the depositing of the oxide or the nitride on the surface of the film that includes the perovskite.

In some embodiments, a film including a perovskite is thermally annealed. The thermal annealing may be performed before or after an oxide or a nitride is deposited on a surface of the film. In some embodiments, a film including a perovskite is not thermally annealed. In some embodiments, (i) before, (ii) after, or (iii) before and after the depositing of the oxide and the nitride, the film including the perovskite is not thermally annealed.

### Perovskite

The perovskites of the composite materials and methods herein may include any known perovskite, such as a metal halide perovskite. In some embodiments, the perovskite is a 3D perovskite. In some embodiments, the perovskite is a 2D perovskite.

In some embodiments, the perovskite is of the following formula:

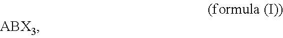

wherein A is a cation, such as an organic cation, wherein B is a metal ion, and wherein X is a halide.

In some embodiments, the perovskite is of the following formula:

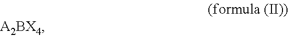

wherein A is a cation, such as an organic cation, wherein B is a metal ion, and wherein X is a halide.

In some embodiments, A of formula (I) or formula (II) is an alkyl ammonium cation. As used herein, the phrase “alkyl ammonium cation” refers to a compound that includes at least one positively charged nitrogen atom, and an alkyl group, such as an alkyl group that includes 1 to 30 carbon atoms. In some embodiments, A of formula (I) or formula (II) is a methylammonium cation.

In some embodiments, B of formula (I) or formula (II) is a metal ion having an oxidation number of +2. In some embodiments, B of formula (I) or formula (II) is Pb²⁺. In some embodiments, B of formula (I) or formula (II) is Sn²⁺.

In some embodiments, X of formula (I) or formula (II) is selected from I⁻, Br⁻, Cl⁻, or a combination thereof. When a combination of halides is selected, the perovskites of formula (I) or formula (II) may be referred to as “mixed halide” perovskites. In some embodiments, X of formula (I) and formula (II) is I⁻. In some embodiments, X of formula (I) and formula (II) is Br⁻. In some embodiments, X of formula (I) and formula (II) is Cl⁻.

In some embodiments, for formula (I) or formula (II), A is a methyl ammonium cation, B is Pb²⁺, and X is I⁻. In some embodiments, for formula (I) or formula (II), A is a methyl ammonium cation, B is Sn²⁺, and X is I⁻.

In some embodiments, for formula (I) or formula (II), A is a methyl ammonium cation, B is Pb²⁺, and X is Br. In some embodiments, for formula (I) or formula (II), A is a methyl ammonium cation, B is Sn²⁺, and X is Br.

In some embodiments, for formula (I) or formula (II), A is a methyl ammonium cation, B is Pb²⁺, and X is Cl⁻. In some embodiments, for formula (I) or formula (II), A is a methyl ammonium cation, B is Sn²⁺, and X is Cl⁻.

### Oxides and Nitrides

The oxides and nitrides of the composite materials and methods may include any of those known in the art, especially those that are compatible with the selected deposition technique, such as ALD. The oxide may be a metal oxide. In some embodiments, the oxide is selected from the group consisting of Al₂O₃, SnO₂, TiO₂, and ZnO. In some embodiments, the nitride is selected from the group consisting of SiNₓ and TiN.

### Electronic Devices

In another aspect, devices are provided herein. The devices may include electronic devices, such as optoelectronic devices. The optoelectronic devices may include a solar cell or a light-emitting diode.

The electronic devices may include any one or more of the composite materials described herein. For example, an electronic device may include one or more layers, and at least one of the layers may be a composite material described herein.

In some embodiments, the film including the perovskite is an emissive layer, a light-absorbing layer, or a charge-transporting layer.

The electronic devices may be prepared using any known techniques. For example a composite material described herein may be substituted with perovskite layers used in known electronic devices (H. Min, et al. Nature 2021, 598, 444; J. Tong, et al. Matter 2021, 4, 1365; J. Zhao, et al. Nat. Photonics 2020, 14, 612; Y. He, et al. Nat. Photonics 2021, 15, 36; H. Zhu, et al. Nat. Mater. 2015, 14, 636; Y. Fu, et al. Nano Lett. 2016, 16, 1000).

All referenced publications are incorporated herein by reference in their entirety. Furthermore, where a definition or use of a term in a reference, which is incorporated by reference herein, is inconsistent or contrary to the definition of that term provided herein, the definition of that term provided herein applies and the definition of that term in the reference does not apply.

While certain aspects of conventional technologies have been discussed to facilitate disclosure of various embodiments, applicants in no way disclaim these technical aspects, and it is contemplated that the present disclosure may encompass one or more of the conventional technical aspects discussed herein.

The present disclosure may address one or more of the problems and deficiencies of known methods and processes. However, it is contemplated that various embodiments may prove useful in addressing other problems and deficiencies in a number of technical areas. Therefore, the present disclosure should not necessarily be construed as limited to addressing any of the particular problems or deficiencies discussed herein.

In this specification, where a document, act or item of knowledge is referred to or discussed, this reference or discussion is not an admission that the document, act or item of knowledge or any combination thereof was at the priority date, publicly available, known to the public, part of common general knowledge, or otherwise constitutes prior art under the applicable statutory provisions; or is known to be relevant to an attempt to solve any problem with which this specification is concerned.

In the descriptions provided herein, the terms “includes,” “is,” “containing,” “having,” and “comprises” are used in an open-ended fashion, and thus should be interpreted to mean “including, but not limited to.” When devices, composite materials, or methods are claimed or described in terms of “comprising” various steps or components, the devices, composite materials, or methods can also “consist essentially of” or “consist of” the various steps or components, unless stated otherwise.

The terms “a,” “an,” and “the” are intended to include plural alternatives, e.g., at least one. For instance, the disclosure of “a perovskite”, “an oxide”, and the like, is meant to encompass one, or mixtures or combinations of more than one perovskite, oxide, and the like, unless otherwise specified.

Various numerical ranges may be disclosed herein. When Applicant discloses or claims a range of any type, Applicant's intent is to disclose or claim individually each possible number that such a range could reasonably encompass, including end points of the range as well as any sub-ranges and combinations of sub-ranges encompassed therein, unless otherwise specified. Moreover, all numerical end points of ranges disclosed herein are approximate. As a representative example, Applicant discloses, in some embodiments, that the film comprising the oxide or the nitride has a thickness of about 3 nm to about 12 nm. This range should be interpreted as encompassing about 3 nm and about 12 nm, and further encompasses “about” each of 4 nm, 5 nm, 6 nm, 7 nm, 8 nm, 9 nm, 10 nm, or 11 nm, including any ranges and sub-ranges between any of these values.

As used herein, the term “about” means plus or minus 10% of the numerical value of the number with which it is being used.

### EXAMPLES

The present invention is further illustrated by the following examples, which are not to be construed in any way as imposing limitations upon the scope thereof. On the contrary, it is to be clearly understood that resort may be had to various other aspects, embodiments, modifications, and equivalents thereof which, after reading the description herein, may suggest themselves to one of ordinary skill in the art without departing from the spirit of the present invention or the scope of the appended claims. Thus, other aspects of this invention will be apparent to those skilled in the art from consideration of the specification and practice of the invention disclosed herein.

### Example 1—Hybrid ALD Protocol

In this example, a hybrid ALD protocol was established that can be used to coat oxide films, such as Al₂O₃ films, directly on films that include a perovskite, such as a film of methylammonium lead iodide (CH₃NH₃PbI₃ or MAPbI₃ for short), which is a specific type of hybrid perovskite commonly incorporated in solar cells with great success.

Combining the thermal and plasma-enhanced modes, the hybrid ALD of this example produced ultrathin coatings with excellent morphological quality, coating efficacy, and chemical compatibility.

Modifying the surface of the perovskite using selected small molecules was determined to be helpful in preparing the surface for ALD. While bare perovskite films could be dissolved by ethanol within minutes, 7 nm of ALD-coated Al₂O₃ was sufficient to protect the underlying perovskite against the solvent for hours.

The improved chemical resistance achieved in this example provided a new path toward stable optoelectronic devices based on hybrid perovskites.

The ALD process used in this example reached atomic-layer precision by delivering alternating precursors in a self-limiting manner (see, e.g., P. O. Oviroh, et al. Sci. Technol. Adv. Mater. 2019, 20, 465). When reaction conditions (e.g. temperature, pressure, and duration) were properly controlled, a single unit-cell layer of coating could be generated during each cycle with a conformal and pinhole-free surface coverage.

Al₂O₃ was used in this example as the model material to demonstrate the capability of applying ALD directly on the hybrid perovskites. The inert chemistry of Al₂O₃ was desirable for interfacial stabilization. Following a widely used ALD protocol (see, e.g., M. D. Groner, et al. Chem. Mater. 2004, 16, 639), trimethyl aluminium (TMA) was used as the source of Al and H₂O as the co-reactant for oxidation.

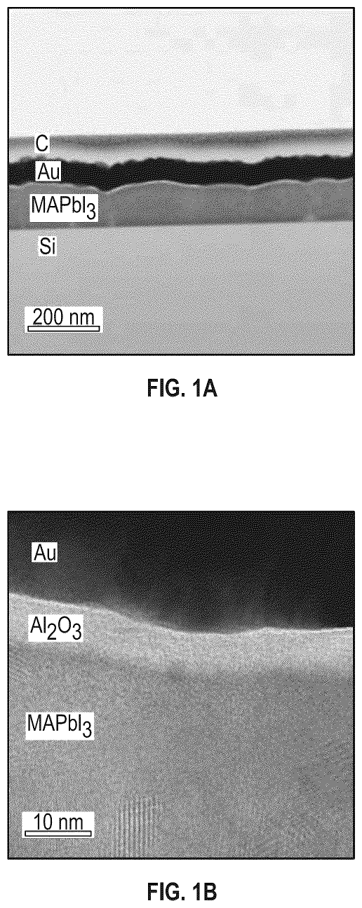

A thin, conformal layer of Al₂O₃ was created successfully on solution-synthesized MAPbI₃, as depicted at FIG. 1A and FIG. 1B. Shown in the cross-section of transmission electron microscopy (TEM) images of FIG. 1A and FIG. 1B, about a 7 nm thick Al₂O₃ film was obtained after 100 cycles of ALD.

Therefore, FIG. 1A and FIG. 1B depicts the successful deposition, via ALD, of Al₂O₃ directly on the perovskite MAPbI₃. FIG. 1A, again, depicts a cross-section TEM image of surface-treated MAPbI₃ coated with 100 cycles of thermal ALD at 90° C. Layers of carbon and platinum, in addition to a 60 nm thick layer of gold were sequentially deposited on top of the ALD layer to improve surface conductivity during the FIB process, and a similar procedure was followed for taking other TEM/STEM images herein. FIG. 1B is a magnified view of the TEM image of FIG. 1A. Additional images of the FFT pattern of the Al₂O₃ and perovskite layer were collected.

FIG. 1C depicts EDS spectrum of the cross-section ALD Al₂O₃ layer depicted in FIG. 1A. A plane-view SEM image of 100 cycles of thermal ALD coated MAPbI₃ also was collected, along with the corresponding EDS mapping of oxygen and aluminum.

The coating appeared to be highly uniform in thickness, and followed the surface contour of the microcrystalline perovskite grains without any noticeable discontinuity (i.e., the coating was pinhole-free in this example).

The fast Fourier transform (FFT) pattern of the TEM image showed that the Al₂O₃ layer was amorphous, which was consistent with the typical crystallinity reported in other ALD-coated Al₂O₃ (see, e.g., M. D. Groner, et al. Chem. Mater. 2004, 16, 639; J. H. Park et al. ACS Nano 2016, 10, 6888; Y. Etinger-Geller et al. Phys. Chem. Chem. Phys. 2019, 21, 14887; Y. Etinger-Geller et al. J. Appl. Phys. 2019, 125, 185302).

The atomic ratio between Al and O was measured using calibrated energy-dispersive X-ray spectroscopy (EDS, integrated with the TEM). This measurement was very close to the 2:3 stoichiometry of Al₂O₃ (see FIG. 1C), which indicated that the precursors were sufficiently reacted under the chosen conditions.

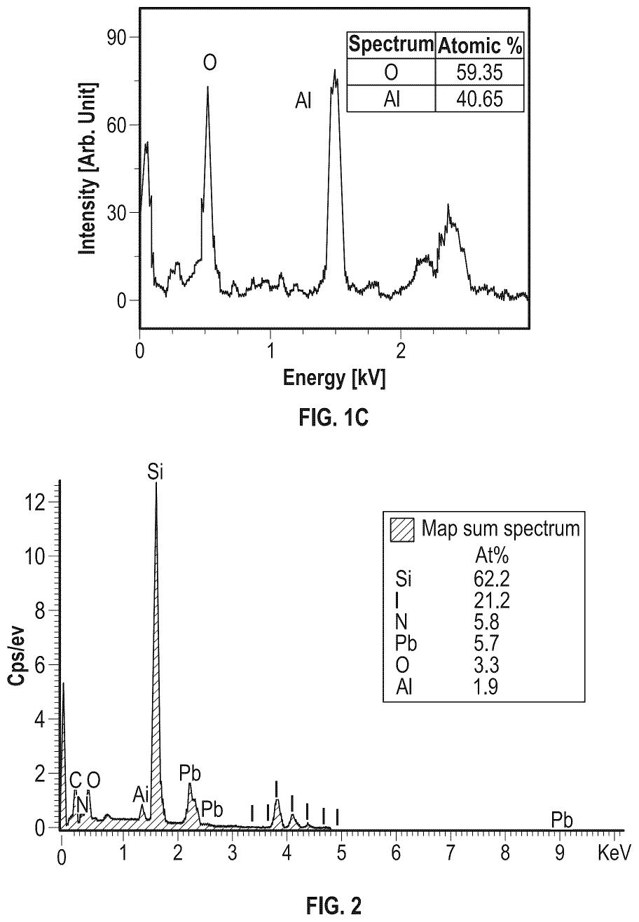

The uniformity of the Al₂O₃ coating was evident at a larger scale in the top-view EDS mapping obtained using a scanning electron microscope (SEM). Microcrystalline morphology of the perovskite layer could be visualized in the secondary electron image that was collected, whereas the EDS mapping showed a homogenous distribution of Al and O across the field of view, with the atomic ratio, again, close to 2:3, as depicted at FIG. 2. FIG. 2 depicts a plane-view EDS of 100 cycles of thermal ALD Al₂O₃ on 2-mcpEtOH treated MAPbI₃ film.

Temperature selection was an important element when conducting ALD directly on MAPbI₃. Hybrid perovskites, because of the organic constituent, can be thermally vulnerable at certain temperatures.

MAPbI₃, for example, was reported to decompose above 250° C. under ambient pressure, which could occur at a lower temperature in vacuum (see, e.g., L. Ma et al. Chem. Mater. 2019, 31, 8515; A. Dualeh et al. Chem. Mater. 2014, 26, 6160). Also, conventional ALD, also known as thermal ALD, can facilitate reactions between precursors and co-reactants by elevating the substrate temperature (see, e.g., J. H. Park, S. et al. ACS Nano 2016, 10, 6888). Although some materials (e.g. Al₂O₃) could be deposited at a moderate or even room temperature, low-temperature processing can compromise coating quality, likely due to insufficient precursor reaction or condensation.

By sweeping the processing temperature while monitoring the physical properties of the perovskite films, a temperature of about 120° C. to about 150° C. was identified to be the highest temperature at which the integrity of MAPbI₃ could be retained confidently in this example (see FIG. 2A and FIG. 2B). At temperatures exceeding this range, the PbI₂ phase appeared in the X-ray diffraction (XRD) patterns, which indicated that thermal decomposition occurred, likely according to the following reaction: MAPbI₃→PbI₂+CH₃I+NH₃ (see, e.g., N. K. Kim et al. Sci. Rep. 2017, 7, 1).

The appearance of PbI₂ was accompanied by changes in optical properties. While the photoluminescence (PL) of MAPbI₃ increased slightly after the surface treatment, as discussed below, much more pronounced effects on the PL intensity were observed after the ALD procedure.

In the temperature range where the integrity of the perovskite layer was preserved, the PL increased after the ALD procedure, which could be attributed to the formation of a small amount of PbI₂ that passivated the non-radiative defects on the surface of MAPbI₃ (see, e.g., B. Shi et al. J. Phys. Chem. C 2018, 122, 21269).

When the substrate temperature was further increased (>120° C.), the PL intensity decreased and PbI₂ started to form. This decrease could have been related to the formation of crystal defects or changes of chemical composition, both of which were undesirable for the best optoelectronic performance in devices. The integrity of the perovskite films was also inspected by topographic mapping using atomic force microscopy (AFM). While the surface topography showed minimal changes at lower temperatures (90 and 100° C.), noticeable grain coalescence was observed in MAPbI₃ films that experienced ALD processing at higher temperatures (120 and 150° C.). Based on the optical, crystallographic and morphological characterizations, 90° C. was identified as an optimal processing temperature for this example. The non-destructive nature of the ALD processing at this temperature was also evident by the retained crystallinity in underlying MAPbI₃ layer.

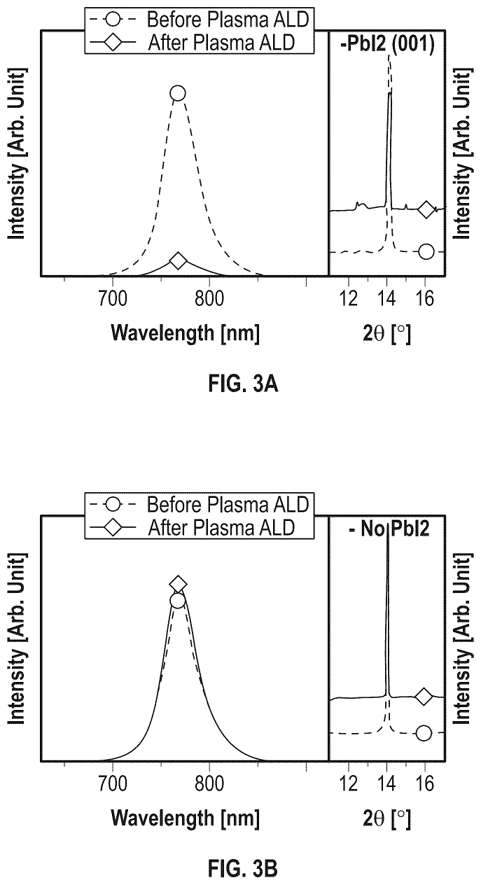

The efficacy of the ALD processing was further improved when the plasma-enhanced mode was introduced. As opposed to the conventional thermal ALD where water vapor was used as a co-reactant, the plasma-enhanced ALD completed coating reactions by generating oxygen radicals using RF plasma generator. This different reaction mechanism allowed for better coating quality at moderate temperatures, likely due to the high reactivity of the energetic oxygen radicals with organometal precursors. These advantages made the plasma-enhanced ALD favorable for depositing directly on the hybrid perovskites. Unfortunately, bare surfaces of the perovskites were subject to plasma damage. After only 20 cycles of plasma-enhanced ALD conducted at 90° C., the perovskite exhibited substantial decays in PL intensity and PbI₂ was detected using XRD (FIG. 3A).

To circumvent the plasma damage, a strategy was employed by combining thermal and plasma-enhanced ALD into the deposition of the same layer of Al₂O₃. The thermal ALD preceded the plasma-enhanced ALD to provide a few monolayers of Al₂O₃ for protection purposes. Surprisingly, 10 cycles of thermal ALD (<1 nm Al₂O₃) were sufficient to protect the underlying perovskite against the plasma damage. Neither photoluminescence nor XRD showed signs of degradation of the perovskite after 10+90 cycles of hybrid ALD (i.e. 10 cycles of thermal ALD followed by 90 cycles of plasma-enhanced ALD) (FIG. 3B). Cross-sectional TEM images showed a slight increase in the thickness of the hybrid ALD coated Al₂O₃ film compared to the one grown by thermal ALD with equal numbers of cycles, which was consistent with the expectation of higher efficacy of plasma-enhanced ALD at moderate temperatures.

The improved coating quality using the hybrid ALD was manifested as much lower permeability against solvents in which the perovskite was known to be soluble. Two MAPbI₃ thin films encapsulated using 10+50 cycles of hybrid ALD and 60 cycles of thermal ALD, respectively, were immersed in the solvents (isopropanol and ethanol). The former showed no visible changes after one hour of immersion whereas the latter was almost completely dissolved. The resistance to strong solvents demonstrated the promise of inhibiting interfacial reactions in perovskite-based devices using ultrathin ALD interlayers.

What also contributed, at least in some instances, to the successful encapsulation was the assembly of selected small molecules on the surface of the perovskite film-a step for preparing the surface for the following ALD. Water has been widely used as the co-reactant in many established ALD recipes when depositing metal oxides. Often, such ALD procedures have begun with a pulse of water vapor to prime the substrates with hydroxyl groups, a desirable termination for receiving the subsequent precursor. Hybrid perovskites, however, have been known to be soluble in water.

Besides the possible surface damages, the perovskites may not be properly primed by the water vapor, which could lead to compromised surface coverage, especially during the first few cycles of thermal ALD. To address this problem, an attempt was made in this example to modify the perovskite surface using 2-mercaptoethanol (HOCH₂CH₂SH, or 2-mcpEtOH), so that the S in the thiol group would bond with Pb²⁺ of the perovskite, likely due to a stronger coordination. Thin films of perovskites were immersed in 2-mcpEtOH vapor in an evacuated quartz tube with controlled temperature and pressure.

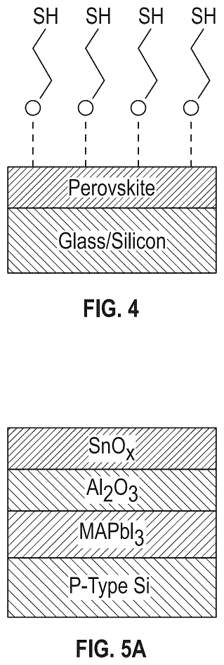

The presence of the surface assembled molecules was confirmed using solid-state 1H-NMR. The hydroxyl protons (OH) and thiol protons (SH) resonated at around 4.9 ppm (H2) and −0.16 ppm (H5), respectively. Interestingly, the bonding configuration of 2-mcpEtOH on the surface of MAPbI₃ turned out to be quite different from what was expected. The integrated areas under the corresponding NMR peaks inferred a greater amount of SH than OH (7.18:2.55) in the molecules attached to the surface (see tables below), which indicated that the perovskite surface was primarily thiolated instead of hydroxylated after the molecular modification (FIG. 4).

### Summary of Proton Compositions from Different Functional Groups as Extracted from Peak Fittings

Summary of Proton Compositions from Different Functional
Groups as Extracted from Peak Fittings

| | H1 | H2 | H3 | H4 | H5 |
|---|---|---|---|---|---|
| | (CH₃NH₃) | (OH) | (CH₃NH₃) | (CH₂) | (SH) |
| Integral area | 39.00 | 2.55 | 40.84 | 10.44 | 7.18 |
| (normalized %) | | | | | |

### Summary of the Proton Peak Information from Solid-State NMR of 2-mcpEtOH Treated MAPbI₃.

Summary of the proton peak information from
solid-state NMR of 2-mcpEtOH treated MAPbI₃.

| | H1 | H2 | H3 | H4 | H5 |
|---|---|---|---|---|---|
| | (CH₃NH₃) | (OH) | (CH₃NH₃) | (CH₂) | (SH) |
| Chemical shift | 6.63 | 4.90 | 3.64 | 1.51 | −0.16 |
| [ppm] | | | | | |
| LB broadening | 331.45 | 557.55 | 305.79 | 951.61 | 1261.27 |
| [Hz] | | | | | |
| Integral area. | 39.00 | 2.55 | 40.84 | 10.44 | 7.18 |
| Normalized % | | | | | |

Despite the unexpected bonding scheme, the surface treatment still led to desirable outcomes in the subsequent ALD. Despite the minimal morphological difference, the ALD-coated samples with the surface molecular modification exhibited considerably stronger chemical resistance. These conclusions were evidenced by cross-sectional TEM images of MAPbI₃ coated with 10+20 cycles of combined ALD with and without 2-mcpEtOH surface treatment; a more completed Al₂O₃ layer was observed in the former. Also, MAPbI₃ film stabilities in isopropanol environment were compared; the two films included a 100-cycle thermal ALD coated MAPbI3 with and without 2-mcpEtOH surface-treatment.

Consistently, Al₂O₃ coated MAPbI₃ films with the 2-mcpEtOH treatment showed less decomposition to PbI₂ after being aged with high humidity. This conclusion was based on a water vapor aging experiment, which was configured to test thermal ALD coating quality. The experiment used a saturated water vapor setup through a sealed quartz tube with water heated up at 60° C., and compared were XRD patterns; specifically, the corresponding PbI₂ (001)/MAPbI₃ (110) peak intensity ratios of ALD-coated MAPbI₃ films with or without 2-mcpEtOH surface-treatment after aging in saturated water vapor environment for 40 hours.

Apparently, the permeable channels in the amorphous Al₂O₃ were microscopic, beyond the spatial resolution of a high-resolution TEM. The morphology, even if imaged using the most sophisticated scanning transmission electron microscopy, might not truly reflect the chemical resistance of the ALD layer.

This example established a protocol to grow a high-quality, pinhole-free, thin layers of Al₂O₃ films directly on MAPbI₃ using ALD. The processing conditions were controlled so that the ALD processing did not degrade the underlying perovskite chemically, morphologically, or optically. The success, in some instances, could be attributed, at least in part, to modifying the surface of perovskite by 2-mercaptoethanol and incorporating the plasma-assisted ALD with the conventional thermal mode. Significant improvement in the chemical resistance against environmental stresses was observed with the ALD encapsulation.

The success with Al₂O₃, the model material used in this example, showed implications on other compounds to be coated on hybrid perovskites using ALD. The alternative coating materials, such as SnO₂ or TiO₂ could exhibit more desirable electrical properties, which could further functionality if used, for example, as an interlayer between the perovskite and the transport layers, or electrodes, in devices.

Chemicals, ALD precursors and gases—CH₃NH₃I (MAI, ≥99.99%) was purchased from Greatcell Solar Materials. Lead iodide (PbI₂, 99%), diethyl ether (≥99.0%), γ-butyrolactone (GBL, ≥99%), and 2-mercaptoethanol (2-mcpEtOH, ≥99.0%) were purchased from Aldrich. Trimethyl aluminium (TMA, ≥98%, pre-packaged in 50 mL Swagelok cylinder) and ultrahigh purity water (H₂O, 99.999%, pre-packaged in 50 mL Swagelok cylinder) were purchased from Strem Chemicals. Acetone (≥99.5%) and isopropanol (≥99.5%) were purchased from BDH VWR Analytical. Argon (Ar, ultra-high purity grade, 300 cf cylinder) and oxygen (O₂, research grade, 300 cf cylinder) were purchased from Airgas. All chemicals were used as received without further purification.

MAPbI₃ perovskite film synthesis—(1:1.05) molar ratio of PbI₂/MAI were first dissolved in GBL with stirring and heating at 40° C. to make 1 M solution. Glass and P-doped silicon wafers were sequentially sonicated in Alconox (1% aqueous detergent solution), deionized water, acetone, and isopropanol for 15 minutes in each step. The precursor solution then was spin-coated in ambient environment on cleaned glass substrates and P-doped silicon wafers by a two-step protocol. Substrates first spun at 200 rpm for 10 s with 85 rpm s⁻¹ ramping rate followed by 3000 rpm for 20 s with the acceleration 340 rpm s⁻¹. The wet films, afterward, were soaked in diethyl ether bath (˜20 mL) for crystallization for ˜30 s. The as-synthesized perovskite films were then thermally annealed at 100° C. on a hot plate in a N₂ glovebox for 10 minutes.

2-mercaptoethanol surface treatment—MAPbI₃ films were surface treated with 2-mercaptoethanol (2-mcpEtOH) vapor in a quartz tube of a tube furnace (Thermo Scientific, Lindberg Blue M). MAPbI₃ films were placed at the centre heating area of the quartz tube, sitting on a glass slide. 50 μL of 2-mcpEtOH in an alumina boat was then placed at the cold side of the furnace, away from the heating coil. The tube was pumped through a mass flow controller (Alicat Scientific) with a 30 Torr pressure set point. The target temperature was set at 80° C., at which surface treatment continued for 30 minutes before the furnace heating was turned off. The MAPbI₃ film were removed after cooling down to below 50° C. under vacuum.

Atomic Layer Deposition (ALD)—ALD Al₂O₃ was deposited with a Fiji G2 system. Reactor chamber was first heated up to the designated ALD growth temperatures and allowed to stabilized for 15 minutes. MAPbI₃ films with and without 2-mcpEtOH surface treatment were first placed in the load lock and pumped below 2×10⁻⁵ Torr before being transferred into the reactor. Before the beginning of ALD growth cycles, carrier Ar and plasma Ar gas were flown through delivery line and ALD reactor at 30 and 80 sccm for 20 s, respectively. Each thermal ALD cycle consisted of TMA pulse of 0.06 s, Ar purge of 5.2 s, H₂O pulse of 0.06 s, then a purge time of 10 s. On the other hand, each plasma ALD cycle was constituted of TMA pulse of 0.06 s, Ar purge of 5.2 s, then a 300 W oxygen plasma of 6 s, as followed by a purge time of 4 s. During the ALD processes, delivery line and valve manifold of the system were kept at 150° C. No pre-and post-deposition thermal annealing of the MAPbI₃ films were performed.

Solid-state ¹H NMR-High—resolution ¹H NMR spectrum of MAPbI₃ was collected on a Bruker 600 MHz spectrometer. The samples were packed into 1.3 mm NMR rotors in an argon-filled glovebox. A rotor-synchronized spin-echo pulse sequence with a π/2pulse length of 2.9 μs was used to acquire the spectrum. The magic angle spinning (MAS) rate was 50 kHz. The NMR spectra were calibrated using adamantane at 1.83 ppm.

### Example 2—SnOₓ ALD on Lead-Halide Perovskites via Surface Functionalization

Inside a Hamilton SafeAire II fume hood, in ambient conditions, PbI₂ and CH₃NH₃I (MAI) were combined together in a glass vial at a 1:1.05 molar ratio. PbI₂ and MAI were dissolved with a solution of N-methyl 2-pyrrolidone (NMP) and gamma butyrolactone (GBL) combined with a 7:3 mass ratio.

The MAPbI₃ solution was then heated and stirred for over 24 hours on a hot plate at 40° C. with the container being taken off the hotplate, shaken by hand, and placed back onto the hotplate periodically. The heating, stirring, and shaking process was repeated until the solution appeared to contain no undissolved salts.

The substrates were prepared depending on the intended measurements for each experiment. For PL and XRD measurements, substrates were made by cutting phosphorus-doped single-crystal Si into wafers about 15 mm×about 10 mm in size.

For experiments less sensitive to substrate choice, substrates made of glass pre-cut by the vendor into about 15 mm by about 10 mm pieces were used. For electrical aging, about 18 mm by about 18 mm glass substrates sputtered with indium tin oxide (ITO) stripes were used. The substrates were then cleaned by sonication in ALCONOX® liquid for 15 minutes, deionized in faucet water for 15 minutes, acetone for 15 minutes, and isopropanol for 15 minutes.

After sonication, the substrates were blow dried with a N₂ gun. To ensure that the interfacial diffusion was isolated to the top electrode interface only during the electrical measurements and cross-sectional scanning electron imaging, titanium oxide (Ti_{y}O_{z}) was coated onto the plasma cleaned substrates by ALD coating the substrates with a recipe including a pulse time of 0.04 s for the TDMAT pulse with a 32 s wait time and 300-watt O₂ plasma pulse for 10 s with a 20 s wait time with a chamber temperature of 50° C. for 200 cycles.

The Ti_{y}O_{z} coated substrates were heated for at least 1 hour at 250° C. at high vacuum inside the reactor chamber to crystallize the Ti_{y}O_{z} by annealing. The substrates were then plasma cleaned with oxygen radical plasma to deposit OH-groups onto the surface of the substrates to increase their hydrophilicity. The substrates were then spin-coated with prepared MAPbI₃ solution for 25 s at 4500 rpm.

The samples were then soaked in 50 mL of diethyl ether for about 1 minute to rinse away the GBL and NMP from the MAPbI₃ solution. The samples were then annealed on a hotplate for 10 minutes inside a nitrogen-filled glovebox to remove the remaining GBL and NMP to make dry, powder polycrystalline MAPbI₃ thin-films.

Vapor Treatment: The samples were surface treated using vapor deposition in a Lindberg BLUEM® tube furnace using 50 μL of β-MeEtOH in an alumina boat in one end of a quartz tube, with the samples carbon taped to a glass microscope slide near the center of the tube. The samples were positioned just far enough from the thermocouple in the center to avoid annealing the samples significantly, but just close enough such that the β-MeEtOH vapor was deposited via adsorption to the Pb²⁺ ions in the MAPbI₃ rather than condensation onto the MAPbI₃ surface, thus resulting in a self-assembled monolayer (SAM) on the MAPbI₃ surface that did not roughen the MAPbI₃.

The tube was then sealed on the end with the alumina boat and vacuumed at 30 torr on the end with the MAPbI₃ samples for 30 minutes while simultaneously being heated to 80° C. After 30 minutes, the furnace was shut off, and the samples were left inside the tube furnace for 10 minutes until the furnace reached 50° C. Upon cooling to 50° C., the samples were then removed from the tube furnace.

ALD Coating: After surface treating, the samples were then ALD coated in a Veeco FIJI® ALD system. For adequate surface passivation of LHPs, Al₂O₃ was used. MAPbI₃ was more robust to the trimethylaluminum (TMA) precursor used for Al₂O₃ ALD than the TDMASn precursor.

Al₂O₃ coated MAPbI₃ also had an increased resistance to degradation due to external chemical stimuli. Furthermore, amorphous Al₂O₃ could impede interfacial ion migration, likely due to its low permeability.

For the Al₂O₃ ALD coating the pulse times used were 0.06 s for the TMA pulse with a 10 s wait time and 0.06 s for the H₂O pulse with a 10 s wait time with a chamber temperature of 90° C. for 10 cycles. Then plasma-assisted ALD was used for an additional 10 cycles with 0.06 s and a 10 s wait time for the TMA pulse and a 6 s pulse of 300-watt O₂ plasma followed by a 4 second wait time. A purpose of the Al₂O₃ primer layer was to ensure that the surface of the MAPbI₃ was sufficiently hydroxylated in addition to providing protection to the MAPbI₃ layer underneath, such that the TDMASn precursor did not damage the MAPbI₃ via an exchange of the MA+ cation with the TDMA ligand.

Shorter pulse times were used to lessen the damage to the MAPbI₃ from the TDMASn and H₂O precursors. However, to ensure that the coating method was ALD rather than pulsed CVD, longer wait times between pulses were used. After Al₂O₃ was deposited on the surface of the MAPbI₃, SnOₓ was deposited with the same ALD reactor. The SnOₓ recipe included a pulse time of 0.04 s for the TDMASn pulse with a 32 s wait time and 0.02 s for the H₂O pulse with a 20 s wait time with a chamber temperature of 60° C. for 100 cycles.

Primer Layer Thickness: The first step in determining if the SnOₓ coating procedure of this example was successful was to determine an effective Al₂O₃ primer coating procedure. Since amorphous Al₂O₃ was much more resistive than oxygen deficient amorphous SnOₓ, one advantageous SnOₓ coating would have a minimally thick Al₂O₃ primer layer to ensure minimal impedance to the charge transport across the interface.

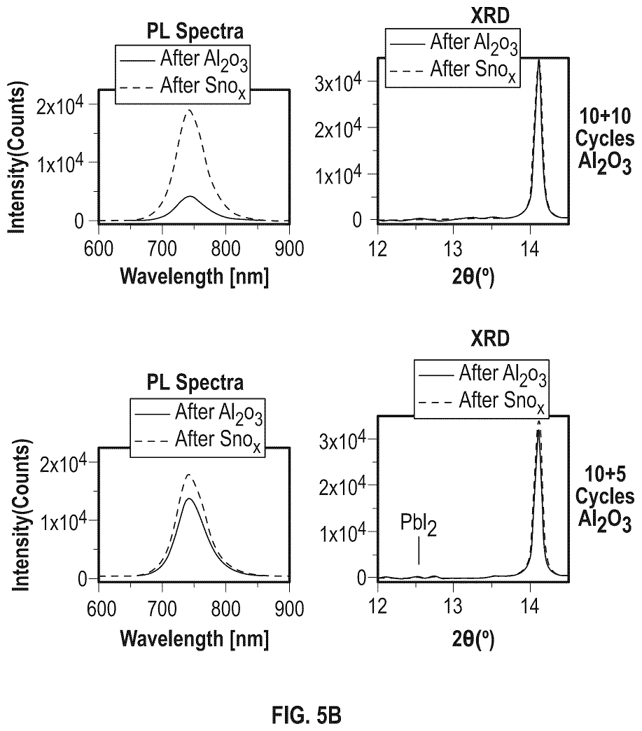

FIG. 5A is a schematic of an ALD coated MAPbI₃ thin-film on a P-type Si substrate. All the data depicted at FIG. 5B was collected with the thin-film architecture of FIG. 5A. According to FIG. 5B, which shows showing the photoluminescence spectra (PL) and the

X-ray diffraction pattern (XRD) for MAPbI₃ samples coated with various Al₂O₃ thicknesses, using 10 thermal cycles and 10 plasma cycles of Al₂O₃ ALD as the primer layer appeared to result in PL enhancement and virtually no PbI₂ formation in the MAPbI₃ layer after the SnOₓ coating step.

The PL enhancement in the samples with thinner Al₂O₃ primer layers was most likely due to a small enough amount of PbI₂ forming in the sample to passivate defects in the MAPbI₃ layer. However, this was still not suitable for charge transport because PbI₂ is resistive and will act as an additional, unwanted tunnel barrier for interfacial charge transport while minimally hindering interfacial ion migration.

In addition to no formation of defects in the crystalline structure of the MAPbI₃ after ALD, Atomic Force Microscopy (AFM) images of the surface of the MAPbI₃ also showed no significant changes to the morphology of the thin film before and after SnOₓ ALD. In addition to no visually observable changes, also calculated was the average roughness of the sample surface, which was about the same before and after SnOₓ ALD on the order of 10 nm using the Nanoscope Analysis package by BRUKER®. Degradation of perovskite is usually enhanced at grain boundaries, so this further indicated that the SnOₓ coating step did not damage the Al₂O₃ primed MAPbI₃ or induce recrystallization of the MAPbI₃ via Ostwald ripening.

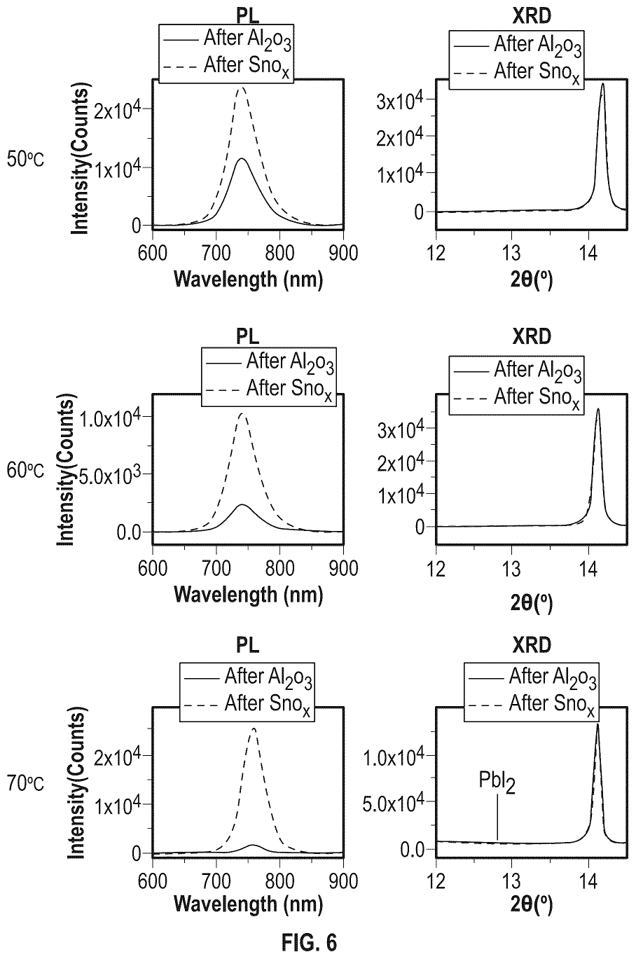

Optimal Coating Temperatures: In obtaining an optimal primer layer thickness for this example, it was found that an optimal temperature for SnOₓ ALD is about 60° C. in this example. According to PL and XRD (FIG. 6), the sample experienced no decomposition into PbI₂ when coated at 60° C. in addition to the PL being enhanced. When coated at 50° C., the sample also did not experience a PL quench nor decomposition into PbI₂. This implied that 60° C. or 50° C. would be suitable SnOₓ coating temperatures, however, coating at 50° C. yielded, in this example, a thinner SnOₓ coating than 60° C. for the same number of cycles. At 70° C., a slight increase in PbI₂ in the sample after the SnOₓ coating step was observed.

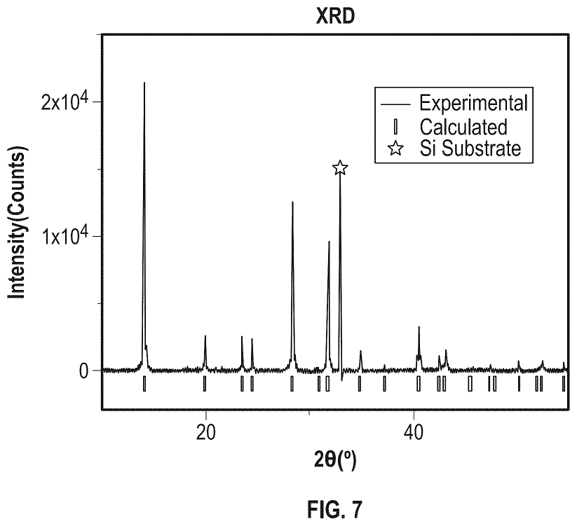

Properties of the Coating: Coating MAPbI₃ with amorphous Al₂O₃, MAPbI₃ gained chemical resistance to air and moisture. Both the SnOₓ and Al₂O₃ coatings were amorphous according to the lack of any additional XRD peaks forming after SnOₓ ALD according to FIG. 7.

To ensure that the MAPbI₃ had metal oxide on the surface, an overhead scanning electron microscope (SEM) image was collected with an energy dispersive spectra (EDS) mapping of an MAPbI₃ sample that was coated with an SnOₓ ALD coating. The EDS map sum spectra showed that there were both Sn and Al atoms in the sample which further bolstered the claim that the ALD coating procedure had deposited SnOₓ on top of the Al₂O₃ coating.

To comparatively test if the hybrid metal-oxide coating successfully increased the chemical resistance of the MAPbI₃ layer the samples were soaked in a less-polar solvent, in this case ethanol (EtOH).

Soaking an uncoated MAPbI₃ sample in EtOH resulted in the sample decomposing into PbI₂ in 2 minutes.

Soaking a sample coated with 10+10 cycles Al₂O₃ and 100 thermal cycles of SnOₓ resulted in the sample not fully decomposed even 18 hours later. The 100 cycles of SnOₓ appeared to provide an additional layer of protection to the MAPbI₃ albeit less overall protection than an aluminum oxide coating of the same thickness. This was most likely because the SnO was amorphous and is therefore less permeable than its crystalline counterpart,¹⁸² but was simultaneously more permeable than amorphous Al₂O₃.

Based on the results of this example, the Al₂O₃ primer layer appeared to have coated MAPbI₃ with SnOₓ ALD without damaging the MAPbI₃ layer. The Al₂O₃ layer also seemed to increase the chemical stability of the MAPbI₃ under exposure to air and solvents.

Materials. In this example, the following materials were used. PbI₂ with ≥99% purity, N-methyl 2-pyrrolidone (NMP) with ≥99% purity and gamma butyrolactone (GBL) with ≥99% purity, beta-mercaptoethanol (B-MeEtOH) with ≥99% purity from Sigma-Aldrich®. CH₃NH₃I (MAI) was purchased from Great Cell Solar Materials® with ≥99% purity. Anhydrous diethyl ether with >99.0% purity from VWR®. TMA, with a purity of >98%, prepackaged in a 50 mL Swagelok cylinder, tetrakisdimethylamino tin (TDMASn) with a purity of ≥98%, prepackaged in a 50 mL Swagelok cylinder, tetrakisdimethylamido titanium (TDMAT) with a purity of >98%, prepackaged in a 50 mL Swagelok cylinder and ultrahigh purity water (H₂O, 99.999%, prepackaged in 50 mL Swagelok cylinder were purchased from Strem Chemicals. The water cylinder was refilled with water from a NANOpur Diamond Analytical water purifier with a 0.2 μm filter with the water having an electrical resistivity of ˜18.2 MΩcm. Acetone (≥99.5%) and isopropanol (>99.5%) were purchased from BDH VWR Analytical. Argon (Ar, ultrahigh purity grade, 300 cf cylinder) and oxygen (O₂, research grade, 300 CF cylinder) were purchased from Airgas. All chemicals were used as received without any further purification.

### Example 3—Testing of Composite Materials for Use in Devices

A series of I-V measurements on ALD coated MAPbI₃ photodiodes is conducted.

The I-V measurements provide insight into the features that make the coatings provided herein, such as the Al₂O₃ coating of Example 2, effective in photovoltaic devices.

If the current is diminished by an undesirable amount, then SnOₓ is coated directly onto the MAPbI₃ without the Al₂O₃ primer layer of Example 2.

According to the cross-sectional EDS, the interfacial ion migration is resolved if the migrated ionic domains are sufficiently large. To obtain sufficiently large ionic domains, the samples are aged by applying voltages at a greater magnitude than VBD to the pristine MAPbI₃ diodes for several hours. Using too harsh of an aging condition can result in burning of the diodes which results in a ionic diffusion, regardless of the ALD coating status which inhibits analysis of the ion blocking capabilities of the metal oxide layer.

Cross-sectional SEM/EDS are collected to compare the pristine and ALD coated diodes, and then higher resolution images using EDS with TEM and STEM are obtained, in order to yield a more definite answer as to whether the interfacial ion migration is suppressed by the metal-oxide coating.

If the ionic diffusion is suppressed, photovoltaic devices prepared with the materials herein are tested.

1. A composite material comprising:
a first film comprising a perovskite, the first film having a first side; and
a second film comprising a first oxide or a first nitride, wherein the second film is disposed on the first side of the first film.

2. The composite material of claim 1, further comprising a third film disposed on the second film, wherein the second film is arranged between the first film and the third film, and the third film comprises a second oxide or a second nitride.

3. The composite material of claim 1, wherein the second film has a thickness of about 3 nm to about 12 nm.

4. The composite material of claim 1, wherein the first side of the first film is functionalized with a thiol.

5. The composite material of claim 1, wherein the perovskite is of formula (I) or formula (II): 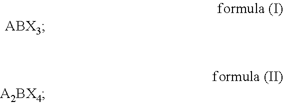
wherein A is an organic cation,
wherein B is a metal ion, and
wherein X is a halide.

6. The method of claim 5, wherein A is an alkyl ammonium cation.

7. The method of claim 5, wherein A is a methyl ammonium cation.

8. The method of claim 5, wherein B is Pb²⁺ or Sn²⁺.

9. The method of claim 5, wherein X is selected from the group consisting of I⁻, Br⁻, and Cl⁻.

10. The composite material of claim 1, wherein the first oxide is selected from the group consisting of Al₂O₃, SnO₂, TiO₂, and ZnO.

11. The composite material of claim 1, wherein the first nitride is selected from the group consisting of Si₃N₄ and TiN.

12. A composite material comprising:
a first film comprising a perovskite, the first film having a first side; and
a second film comprising a first oxide or a first nitride, wherein the second film is disposed on the first side of the first film;
wherein the second film has a thickness of about 3 nm to about 12 nm;
wherein the first side of the first film is functionalized with a thiol; and
wherein the perovskite is of formula (I) or formula (II)— 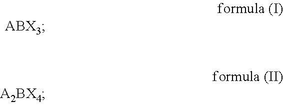
wherein A is an alkyl ammonium cation,
wherein B is Pb²⁺ or Sn²⁺, and
wherein X is a halide.

13. The composite material of claim 12, wherein the first oxide is selected from the group consisting of Al₂O₃, SnO₂, TiO₂, and ZnO.

14. The composite material of claim 12, wherein the first nitride is selected from the group consisting of Si₃N₄ and TiN.

15. The composite material of claim 12, wherein the perovskite is of formula (II).

16. The composite material of claim 12, further comprising a third film disposed on the second film, wherein the second film is arranged between the first film and the third film, and the third film comprises a second oxide or a second nitride.

17. The composite material of claim 16, wherein the second oxide is selected from the group consisting of Al₂O₃, SnO₂, TiO₂, and ZnO, and wherein the second nitride is selected from the group consisting of Si₃N₄ and TiN.

18. An electronic device comprising the composite material of claim 1.

19. The electronic device of claim 18, wherein the first film is an emissive layer.

20. The electronic device of claim 18, wherein the first film is a light-absorbing layer or a charge-transporting layer.
